(19) United States
(12) Patent Application Publication
(10) Pub. No.: US 2023/0192474 A1
(43) Pub. Date: Jun. 22, 2023

(54) MEMS Spacer Assembly

(71) Applicant: MEMS DRIVE (NANJING) CO., LTD, Nanjing (CN)

(72) Inventors: Matthew Ng, Rosemead, CA (US); Guiqin Wang, Arcadia, CA (US)

(21) Appl. No.: 18/067,447

(22) Filed: Dec. 16, 2022

Related U.S. Application Data
(60) Provisional application No. 63/291,197, filed on Dec. 17, 2021.

(51) Int. Cl. B81B 3/00; H04N 23/55; H04N 23/68

(52) U.S. Cl. CPC B81B 3/0021; H04N 23/55; H04N 23/685; B81B 2203/0136; B81B 2203/0118; B81B 2201/033; B81B 2207/091

(57) ABSTRACT

A spacer assembly includes: an essentially-planer structural portion configured to position an image sensor on a MEMS actuator; an outer sub-portion configured to be mounted to the MEMS actuator; and an inner sub-portion configured to mount the image sensor.

### RELATED CASE(S)

This application claims the benefit of U.S. Provisional Application No. 63/291,197 filed on 17 Dec. 2021; the contents of which are incorporated herein by reference.

### TECHNICAL FIELD

This disclosure relates to actuators in general and, more particularly, to miniaturized MEMS actuators configured for use within camera packages.

### BACKGROUND

As is known in the art, actuators may be used to convert electronic signals into mechanical motion. In many applications such as e.g., portable devices, imaging-related devices, telecommunications components, and medical instruments, it may be beneficial for miniature actuators to fit within the small size, low power, and cost constraints of these application.

Micro-electrical-mechanical system (MEMS) technology is the technology that in its most general form may be defined as miniaturized mechanical and electro-mechanical elements that are made using the techniques of microfabrication. The critical dimensions of MEMS devices may vary from well below one micron to several millimeters. In general, MEMS actuators are more compact than conventional actuators, and they consume less power.

### SUMMARY OF DISCLOSURE

In one implementation, a spacer assembly includes: an essentially-planer structural portion configured to position an image sensor on a MEMS actuator; an outer sub-portion configured to be mounted to the MEMS actuator; and an inner sub-portion configured to mount the image sensor.

One or more of the following features may be included. The outer sub-portion may be is configured to be mounted to the MEMS actuator with an epoxy. The inner sub-portion may be configured to mount the image sensor with an epoxy. The essentially-planer structural portion may include one or more relief assemblies configured to enable electrically-connecting the image sensor and the MEMS actuator. The essentially-planer structural portion may include one or more movement restriction assemblies configured to prevent undesired movement of the image sensor. The undesired movement of the image sensor may include drop-induced movement of the image sensor. The one or more movement restriction assemblies may be configured to limit movement in the X axis & Y axis. The one or more movement restriction assemblies may be configured to essentially prevent movement in the Z axis. The one or more movement restriction assemblies may be configured to interface with one or more stop assemblies. The one or more stop assemblies may be a portion of a holder assembly. The spacer assembly may be constructed of metal.

In another implementation, a spacer assembly includes: an essentially-planer structural portion configured to position an image sensor on a MEMS actuator; an outer sub-portion configured to be mounted to the MEMS actuator with an epoxy; and an inner sub-portion configured to mount the image sensor with an epoxy.

One or more of the following features may be included. The essentially-planer structural portion may include one or more relief assemblies configured to enable electrically-connecting the image sensor and the MEMS actuator. The essentially-planer structural portion may include one or more movement restriction assemblies configured to prevent undesired movement of the image sensor. The undesired movement of the image sensor may include drop-induced movement of the image sensor. The one or more movement restriction assemblies may be configured to limit movement in the X axis & Y axis. The one or more movement restriction assemblies may be configured to essentially prevent movement in the Z axis. The one or more movement restriction assemblies may be configured to interface with one or more stop assemblies. The one or more stop assemblies may be a portion of a holder assembly.

In another implementation, a spacer assembly includes: an essentially-planer structural portion configured to position an image sensor on a MEMS actuator; an outer sub-portion configured to be mounted to the MEMS actuator; and an inner sub-portion configured to mount the image sensor; wherein the essentially-planer structural portion includes one or more movement restriction assemblies configured to prevent undesired movement of the image sensor.

One or more of the following features may be included. The undesired movement of the image sensor may include drop-induced movement of the image sensor. The one or more movement restriction assemblies may be configured to limit movement in the X axis & Y axis. The one or more movement restriction assemblies may be configured to essentially prevent movement in the Z axis. The one or more movement restriction assemblies may be configured to interface with one or more stop assemblies. The one or more stop assemblies may be a portion of a holder assembly.

The details of one or more implementations are set forth in the accompanying drawings and the description below. Other features and advantages will become apparent from the description, the drawings, and the claims.

### BRIEF DESCRIPTION OF THE DRAWINGS

FIG. 1 is a perspective view of a MEMS package in accordance with various embodiments of the present disclosure;

FIG. 2A is a diagrammatic view of an in-plane MEMS actuator with the optoelectronic device in accordance with various embodiments of the present disclosure;

FIG. 2B is a perspective view of an in-plane MEMS actuator with the optoelectronic device in accordance with various embodiments of the present disclosure;

FIG. 3 is a diagrammatic view of an in-plane MEMS actuator in accordance with various embodiments of the present disclosure;

FIG. 4 is a diagrammatic view of a comb drive sector in accordance with various embodiments of the present disclosure;

FIG. 5 is a diagrammatic view of a comb pair in accordance with various embodiments of the present disclosure;

FIG. 6 is a diagrammatic view of fingers of the comb pair of FIG. 5 in accordance with various embodiments of the present disclosure;

FIGS. 7A-7B are diagrammatic views of a spacer assembly in accordance with various embodiments of the present disclosure; and

FIG. 8 is a diagrammatic view of a MEMS package in accordance with various embodiments of the present disclosure.

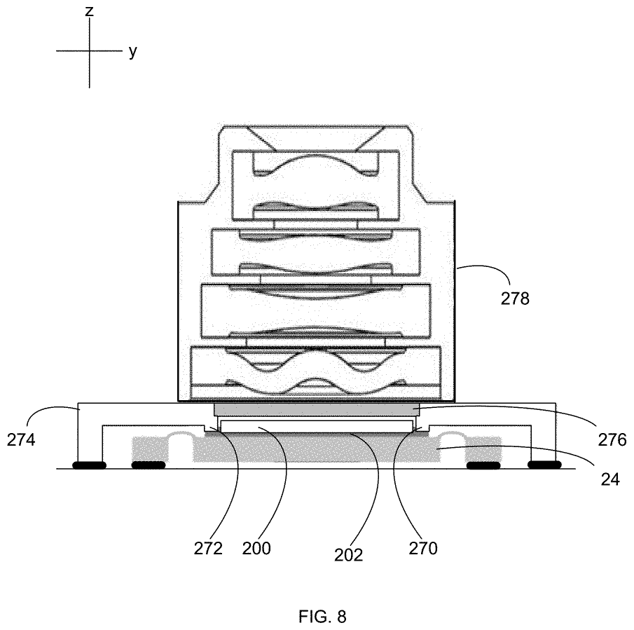

Like reference symbols in the various drawings indicate like elements.

### DETAILED DESCRIPTION OF THE PREFERRED EMBODIMENTS

### System Overview:

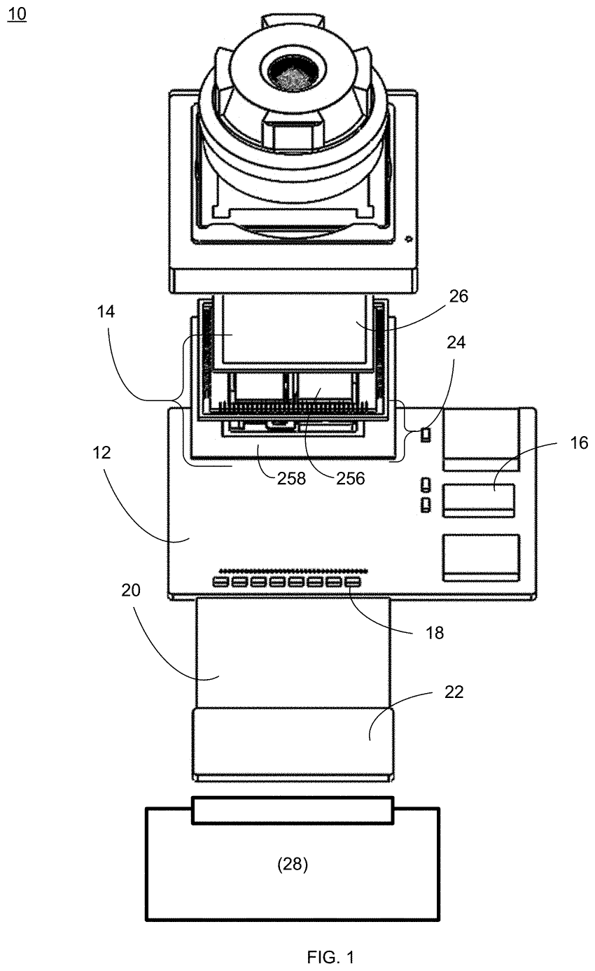

Referring to FIG. 1, there is shown MEMS package 10, in accordance with various aspects of this disclosure. In this example, MEMS package 10 is shown to include printed circuit board 12, multi-axis MEMS assembly 14, driver circuits 16, electronic components 18, flexible circuit 20, and electrical connector 22. Multi-axis MEMS assembly 14 may include micro-electrical-mechanical system (MEMS) actuator 24 (configured to provide linear three-axis movement) and optoelectronic device 26 coupled to micro-electrical-mechanical system (MEMS) actuator 24.

As will be discussed below in greater detail, examples of micro-electrical-mechanical system (MEMS) actuator 24 may include but are not limited to an in-plane MEMS actuator, an out-of-plane MEMS actuator, and a combination in-plane/out-of-plane MEMS actuator. For example and if micro-electrical-mechanical system (MEMS) actuator 24 is an in-plane MEMS actuator, the in-plane MEMS actuator may include an electrostatic comb drive actuation system (as will be discussed below in greater detail). Additionally, if micro-electrical-mechanical system (MEMS) actuator 24 is an out-of-plane MEMS actuator, the out-of-plane MEMS actuator may include a piezoelectric actuation system or electrostatic actuation. And if micro-electrical-mechanical system (MEMS) actuator 24 is a hybrid in-plane/out-of-plane MEMS actuator, the combination in-plane/out-of-plane MEMS actuator may include an electrostatic comb drive actuation system and a piezoelectric actuation system.

As will be discussed below in greater detail, examples of optoelectronic device 26 may include but are not limited to an image sensor, a holder assembly, an IR filter and/or a lens assembly. Examples of electronic components 18 may include but are not limited to various electronic or semiconductor components and devices. Flexible circuit 20 and/or connector 22 may be configured to electrically couple MEMS package 10 to e.g., a smart phone or a digital camera (represented as generic item 28).

In some embodiments, some of the components of MEMS package 10 may be joined together using various epoxies/adhesives. For example, an outer frame of micro-electrical-mechanical system (MEMS) actuator 24 may include contact pads that may correspond to similar contact pads on printed circuit board 12.

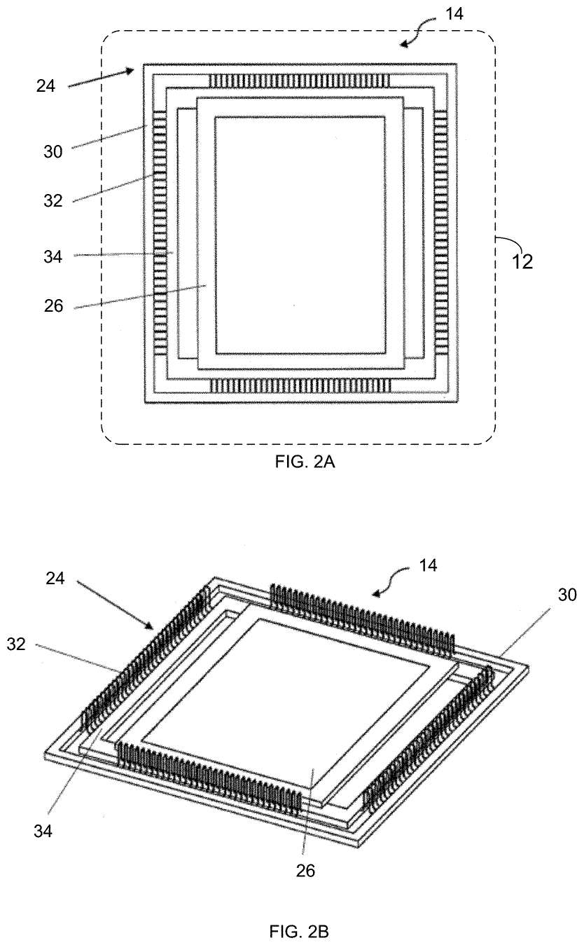

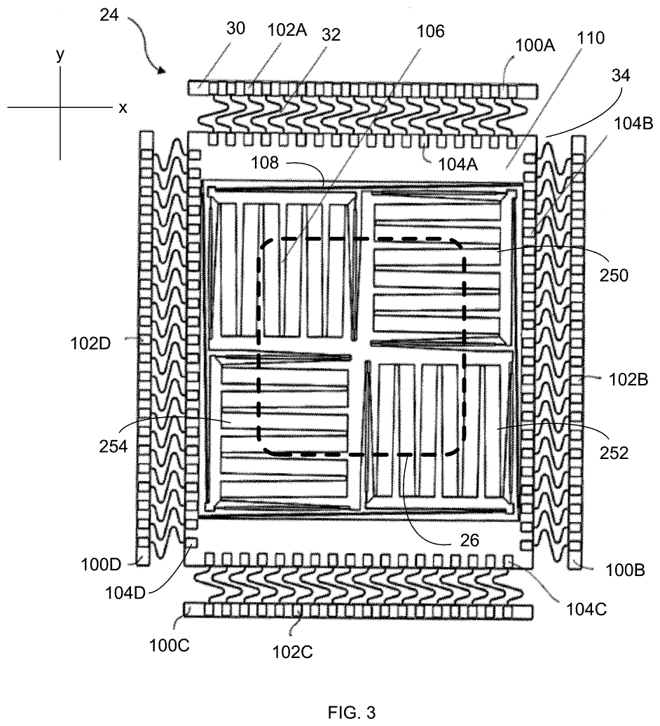

Referring also to FIG. 2A, there is shown multi-axis MEMS assembly 14, which may include optoelectronic device 26 coupled to micro-electrical-mechanical system (MEMS) actuator 24. As discussed above, examples of micro-electrical-mechanical system (MEMS) actuator 24 may include but are not limited to an in-plane MEMS actuator, an out-of-plane MEMS actuator, and a combination in-plane/out-of-plane MEMS actuator.

When configured to provide in-plane actuation functionality, micro-electrical-mechanical system (MEMS) actuator 24 may include outer frame 30, plurality of electrically conductive flexures 32, MEMS actuation core 34 for attaching a payload (e.g., a device), and attached optoelectronic device 26. Optoelectronic device 26 may be coupled to MEMS actuation core 34 of micro-electrical-mechanical system (MEMS) actuator 24 by epoxy (or various other adhesives/materials and/or bonding methods).

Referring also to FIG. 2B, plurality of electrically conductive flexures 32 of micro-electrical-mechanical system (MEMS) actuator 24 may be curved upward and buckled to achieve the desired level of flexibility & compression. In the illustrated embodiment, plurality of electrically conductive flexures 32 may have one end attached to MEMS actuation core 34 (e.g., the moving portion of micro-electrical-mechanical system (MEMS) actuator 24) and the other end attached to outer frame 30 (e.g., the fixed portion of micro-electrical-mechanical system (MEMS) actuator 24).

Plurality of electrically conductive flexures 32 may be conductive wires that may extend above the plane (e.g., an upper surface) of micro-electrical-mechanical system (MEMS) actuator 24 and may electrically couple laterally separated components of micro-electrical-mechanical system (MEMS) actuator 24. For example, plurality of electrically conductive flexures 32 may provide electrical signals from optoelectronic device 26 and/or MEMS actuation core 34 to outer frame 30 of micro-electrical-mechanical system (MEMS) actuator 24. As discussed above, outer frame 30 of micro-electrical-mechanical system (MEMS) actuator 24 may be affixed to circuit board 12 using epoxy (or various other adhesive materials or devices).

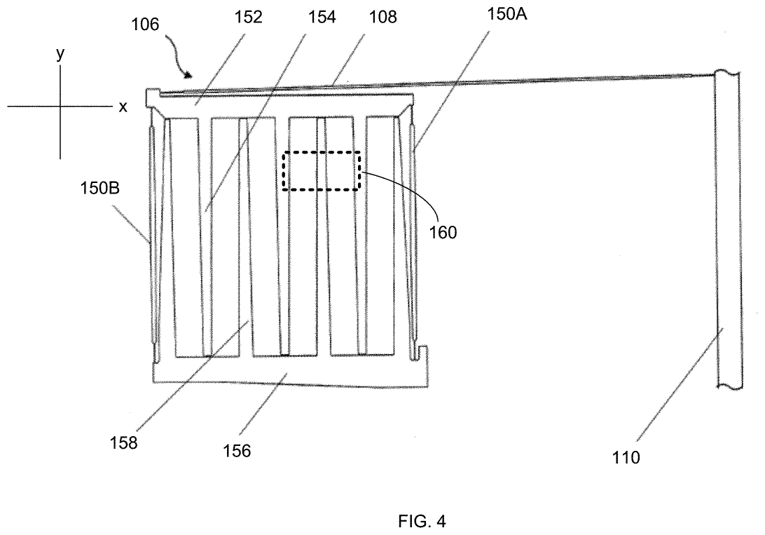

Referring also to FIG. 3, there is shown a top view of micro-electrical-mechanical system (MEMS) actuator 24 in accordance with various embodiments of the disclosure. Outer frame 30 is shown to include (in this example) four frame assemblies (e.g., frame assembly 100A, frame assembly 100B, frame assembly 100C, frame assembly 100D) that are shown as being spaced apart to allow for additional detail.

Outer frame 30 of micro-electrical-mechanical system (MEMS) actuator 24 may include a plurality of contact pads (e.g., contact pads 102A on frame assembly 100A, contact pads 102B on frame assembly 100B, contact pads 102C on frame assembly 100C, and contact pads 102D on frame assembly 100D), which may be electrically coupled to one end of plurality of electrically conductive flexures 32. The curved shape of electrically conductive flexures 32 is provided for illustrative purposes only and, while illustrating one possible embodiment, other configurations are possible and are considered to be within the scope of this disclosure.

MEMS actuation core 34 may include a plurality of contact pads (e.g., contact pads 104A, contact pads 104B, contact pads 104C, contact pads 104D), which may be electrically coupled to the other end of plurality of electrically conductive flexures 32. A portion of the contact pads (e.g., contact pads 104A, contact pads 104B, contact pads 104C, contact pads 104D) of MEMS actuation core 34 may be electrically coupled to optoelectronic device 26 by wire bonding, silver paste, or eutectic seal, thus allowing for the electrical coupling of optoelectronic device 26 to outer frame 30.

### Electrostatic Actuation

MEMS actuation core 34 may include one or more comb drive sectors (e.g., comb drive sector 106) that are actuation sectors disposed within micro-electrical-mechanical system (MEMS) actuator 24. The comb drive sectors (e.g., comb drive sector 106) within MEMS actuation core 34 may be disposed in the same plane and may be positioned orthogonal to each other to allow for movement in two axes (e.g., the X-axis and the Y-axis). Accordingly, the in-plane MEMS actuator generally (and MEMS actuation core 34 specifically) may be configured to provide linear X-axis movement and linear Y-axis movement.

While in this particular example, MEMS actuation core 34 is shown to include four comb drive sectors, this is for illustrative purposes only and is not intended to be a limitation of this disclosure, as other configurations are possible. For example, the number of comb drive sectors may be increased or decreased depending upon design criteria.

While in this particular example, the four comb drive sectors are shown to be generally square in shape, this is for illustrative purposes only and is not intended to be a limitation of this disclosure, as other configurations are possible. For example, the shape of the comb drive sectors may be changed to meet various design criteria.

While the comb drive sectors (e.g., comb drive sector 106) within MEMS actuation core 34 are shown to be positioned orthogonal to each other to allow for movement in two axes (e.g., the X-axis and the Y-axis), this is for illustrative purposes only and is not intended to be a limitation of this disclosure, as other configurations are possible. For example, the comb drive sectors (e.g., comb drive sector 106) within MEMS actuation core 34 may be positioned parallel to each other to allow for movement in a single axis (e.g., either the X-axis or the Y-axis).

Each comb drive sector (e.g., comb drive sector 106) within MEMS actuation core 34 may include one or more moving portions and one or more fixed portions. As will be discussed below in greater detail, a comb drive sector (e.g., comb drive sector 106) within MEMS actuation core 34 may be coupled, via a cantilever assembly (e.g., cantilever assembly 108), to outer periphery 110 of MEMS actuation core 34 (i.e., the portion of MEMS actuation core 34 that includes contact pads 104A, contact pads 104B, contact pads 104C, contact pads 104D), which is the portion of MEMS actuation core 34 to which optoelectronic device 26 may be coupled, thus effectuating the transfer of movement to optoelectronic device 26.

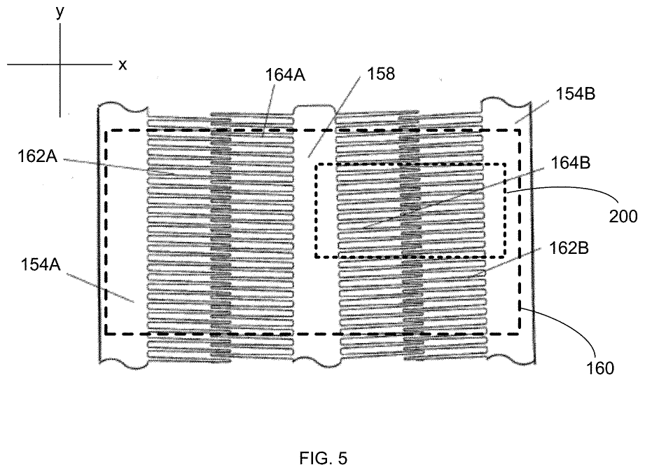

Referring also to FIG. 4, there is shown a top view of comb drive sector 106 in accordance with various embodiments of the present disclosure. Each comb drive sector (e.g., comb drive sector 106) may include one or more motion control cantilever assemblies (e.g., motion control cantilever assemblies 150A, 150B) positioned outside of comb drive sector 106, moveable frame 152, moveable spines 154, fixed frame 156, fixed spines 158, and cantilever assembly 108 that is configured to couple moving frame 152 to outer periphery 110 of MEMS actuation core 34. In this particular configuration, motion control cantilever assemblies 150A, 150B may be configured to prevent Y-axis displacement between moving frame 152/moveable spines 154 and fixed frame 156/fixed spines 158.

Comb drive sector 106 may include a movable member including moveable frame 152 and multiple moveable spines 154 that are generally orthogonal to moveable frame 152. Comb drive sector 106 may also include a fixed member including fixed frame 156 and multiple fixed spines 158 that are generally orthogonal to fixed frame 156. Cantilever assembly 108 may be deformable in one direction (e.g., in response to Y-axis deflective loads) and rigid in another direction (e.g., in response to X-axis tension and compression loads), thus allowing for cantilever assembly 108 to absorb motion in the Y-axis but transfer motion in the X-axis.

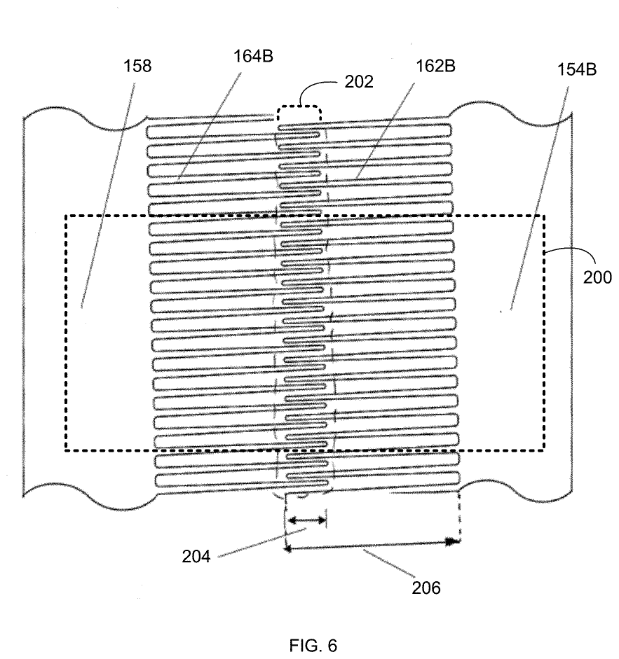

Referring also to FIG. 5, there is shown a detail view of portion 160 of comb drive sector 106. Moveable spines 154A, 154B may include a plurality of discrete moveable actuation fingers that are generally orthogonally-attached to moveable spines 154A, 154B. For example, moveable spine 154A is shown to include moveable actuation fingers 162A and moveable spine 154B is shown to include moveable actuation fingers 162B.

Further, fixed spine 158 may include a plurality of discrete fixed actuation fingers that are generally orthogonally-attached to fixed spine 158. For example, fixed spine 158 is shown to include fixed actuation fingers 164A that are configured to mesh and interact with moveable actuation fingers 162A. Further, fixed spine 158 is shown to include fixed actuation fingers 164B that are configured to mesh and interact with moveable actuation fingers 162B.

Accordingly, various numbers of actuation fingers may be associated with (i.e., coupled to) the moveable spines (e.g., moveable spines 154A, 154B) and/or the fixed spines (e.g., fixed spine 158) of comb drive sector 106. As discussed above, each comb drive sector (e.g., comb drive sector 106) may include two motion control cantilever assemblies 150A, 150B separately placed on each side of comb drive sector 106. Each of the two motion control cantilever assemblies 150A, 150B may be configured to couple moveable frame 152 and fixed frame 156, as this configuration enables moveable actuation fingers 162A, 162B to be displaceable in the X-axis with respect to fixed actuation fingers 164A, 164B (respectively) while preventing moveable actuation fingers 162A, 162B from being displaced in the Y-axis and contacting fixed actuation fingers 164A, 164B (respectively).

While actuation fingers 162A, 162B, 164A, 164B (or at least the center axes of actuation fingers 162A, 162B, 164A, 164B) are shown to be generally parallel to one another and generally orthogonal to the respective spines to which they are coupled, this is for illustrative purposes only and is not intended to be a limitation of this disclosure, as other configurations are possible. Further and in some embodiments, actuation fingers 162A, 162B, 164A, 164B may have the same width throughout their length and in other embodiments, actuation fingers 162A, 162B, 164A, 164B may be tapered.

Further and in some embodiments, moveable frame 152 may be displaced in the positive X-axis direction when a voltage potential is applied between actuation fingers 162A and actuation fingers 164A, while moveable frame 152 may be displaced in the negative X-axis direction when a voltage potential is applied between actuation fingers 162B and actuation fingers 164B.

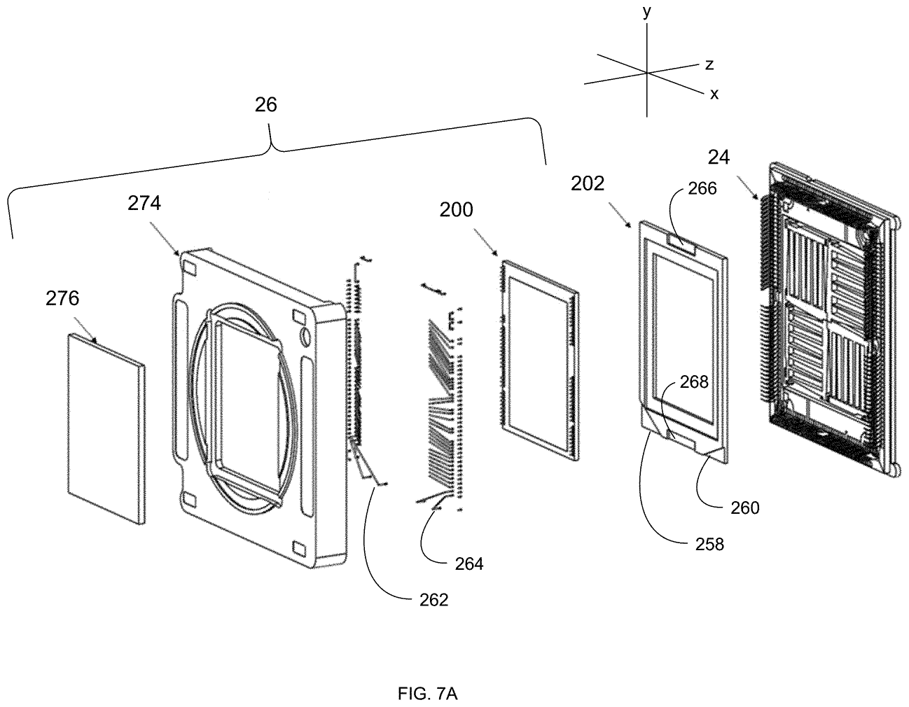

Referring also to FIG. 6, there is shown a detail view of portion 200 of comb drive sector 106. Fixed spine 158 may be generally parallel to moveable spine 154B, wherein actuation fingers 164B and actuation fingers 162B may overlap within region 202, wherein the width of overlap region 202 is typically in the range of 10-50 microns. While overlap region 202 is described as being in the range of 10-50 microns, this is for illustrative purposes only and is not intended to be a limitation of this disclosure, as other configurations are possible.

Overlap region 202 may represent the distance 204 where the ends of actuation fingers 162B extends past and overlap the ends of actuation fingers 164B, which are interposed therebetween. In some embodiments, actuation fingers 162B and actuation fingers 164B may be tapered such that their respective tips are narrower than their respective bases (i.e., where they are attached to their spines). As is known in the art, various degrees of taper may be utilized with respect to actuation fingers 162B and actuation fingers 164B. Additionally, the overlap of actuation fingers 162B and actuation fingers 164B provided by overlap region 202 may help ensure that there is sufficient initial actuation force when an electrical voltage potential is applied so that MEMS actuation core 34 may move gradually and smoothly without any sudden jumps when varying the applied voltage. The height of actuation fingers 162B and actuation fingers 164B may be determined by various aspects of the MEMS fabrication process and various design criteria.

Length 206 of actuation fingers 162B and actuation fingers 164B, the size of overlap region 202, the gaps between adjacent actuation fingers, and actuation finger taper angles that are incorporated into various embodiments may be determined by various design criteria, application considerations, and manufacturability considerations, wherein these measurements may be optimized to achieve the required displacement utilizing the available voltage potential.

As shown in FIG. 3 and as discussed above, MEMS actuation core 34 may include one or more comb drive sectors (e.g., comb drive sector 106), wherein the comb drive sectors (e.g., comb drive sector 106) within MEMS actuation core 34 may be disposed in the same plane and may be positioned orthogonal to each other to allow for movement in two axes (e.g., the X-axis and the Y-axis).

Specifically and in this particular example, MEMS actuation core 34 is shown to include four comb drive sectors (e.g., comb drive sectors 106, 250, 252, 254). As discussed above, comb drive sector 106 is configured to allow for movement along the X-axis, while preventing movement along the Y-axis. As comb drive sector 252 is similarly configured, comb drive sector 252 may allow for movement along the X-axis, while preventing movement along the Y-axis. Accordingly, if a signal is applied to comb drive sector 106 that provides for positive X-axis movement, while a signal is applied to comb drive sector 252 that provides for negative X-axis movement, actuation core 34 may be displaced in a clockwise direction. Conversely, if a signal is applied to comb drive sector 106 that provides for negative X-axis movement, while a signal is applied to comb drive sector 252 that provides for positive X-axis movement, actuation core 34 may be displaced in a counterclockwise direction.

Further, comb drive sectors 250, 254 are configured (in this example) to be orthogonal to comb drive sectors 106, 252. Accordingly, comb drive sectors 250, 254 may be configured to allow for movement along the Y-axis, while preventing movement along the X-axis. Accordingly, if a signal is applied to comb drive sector 250 that provides for positive Y-axis movement, while a signal is applied to comb drive sector 254 that provides for negative Y-axis movement, actuation core 34 may be displaced in a counterclockwise direction. Conversely, if a signal is applied to comb drive sector 250 that provides for negative Y-axis movement, while a signal is applied to comb drive sector 254 that provides for positive Y-axis movement, actuation core 34 may be displaced in a clockwise direction.

Accordingly, the in-plane MEMS actuator generally (and MEMS actuation core 34 specifically) may be configured to provide rotational (e.g., clockwise or counterclockwise) Z-axis movement

### Spacer Assembly

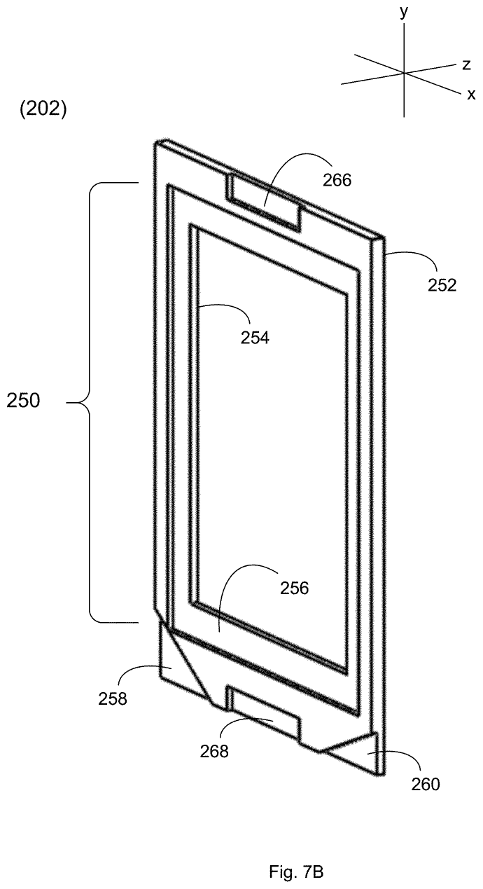

As discussed above, examples of optoelectronic device 26 may include but are not limited to an image sensor, a holder assembly, an IR filter and/or a lens assembly. Referring also to FIGS. 7A, 7B & 8, in order to enable micro-electrical-mechanical system (MEMS) actuator 24 to be utilized with a plurality of differently-sized image sensors (e.g., image sensor 200), spacer assembly 202 may be utilized to “resize” a “smaller” image sensor (e.g., image sensor 200) for use with a “larger” micro-electrical-mechanical system (MEMS) actuator 24.

Specifically and as will be discussed below in greater detail, spacer assembly 202 may be mounted to micro-electrical-mechanical system (MEMS) actuator 24 and image sensor 200 may be mounted to spacer assembly 202, thus indirectly mounting image sensor 200 to micro-electrical-mechanical system (MEMS) actuator 24 via spacer assembly 202.

Spacer assembly 202 may include essentially-planer structural portion 250 configured to position the image sensor (e.g., image sensor 200) on the micro-electrical-mechanical system (MEMS) actuator 24. Spacer assembly 202 may include an outer sub-portion (e.g., outer sub-portion 252) configured to be mounted to the micro-electrical-mechanical system (MEMS) actuator 24; and an inner sub-portion (e.g., inner sub-portion 254) configured to mount the image sensor (e.g., image sensor 200). For example, outer sub-portion 252 may be configured to be mounted to micro-electrical-mechanical system (MEMS) actuator 24 with an epoxy (or various other adhesive materials or devices) and/or inner sub-portion 254 may be configured to mount the image sensor (e.g., image sensor 200) with an epoxy (or various other adhesive materials or devices). Inner sub-portion 254 may include a recess (e.g., recess 256) sized to receive the image sensor (e.g., image sensor 200). Spacer assembly 202 may be constructed of a plastic or a metal (e.g., stainless steel or aluminum).

The essentially-planer structural portion (e.g., essentially-planer structural portion 250) may include one or more relief assemblies (e.g., relief assemblies 258, 260) configured to enable electrically-connecting the image sensor (e.g., image sensor 200) and the MEMS actuator (e.g., micro-electrical-mechanical system (MEMS) actuator 24). For example, the relief assemblies (e.g., relief assemblies 258, 260) may be configured to allow the use of wirebonding (e.g., wirebonding 262, 264) to electrically-connect the image sensor (e.g., image sensor 200) and the MEMS actuator (e.g., micro-electrical-mechanical system (MEMS) actuator 24).

The essentially-planer structural portion (e.g., essentially-planer structural portion 250) may include one or more movement restriction assemblies (e.g., movement restriction assemblies 266, 268) configured to prevent undesired movement of the image sensor (e.g., image sensor 200). Examples of such undesired movement of the image sensor (e.g., image sensor 200) may include drop-induced movement of image sensor 200, such as that caused by someone dropping their smart phone or digital camera (represented as generic item 28).

The one or more movement restriction assemblies (e.g., movement restriction assemblies 266, 268) may be configured to limit movement in the X axis & Y axis. As discussed above, the MEMS actuator (e.g., micro-electrical-mechanical system (MEMS) actuator 24) may be configured to allow movement in the X axis & Y axis. So if the desired level of XY movement is 90 the one or more movement restriction assemblies (e.g., movement restriction assemblies 266, 268) may be configured to limit movement in the X axis & Y axis to 100 μM.

Further, the one or more movement restriction assemblies (e.g., movement restriction assemblies 266, 268) may be configured to essentially prevent movement in the Z axis. So if the desired level of Z movement is 0 the one or more movement restriction assemblies (e.g., movement restriction assemblies 266, 268) may be configured to limit movement in the Z axis to 10 μM.

The one or more movement restriction assemblies (e.g., movement restriction assemblies 266, 268) may be configured to interface with one or more stop assemblies (e.g., stop assemblies 270, 272). These one or more stop assemblies (e.g., stop assemblies 270, 272) may be a portion of a holder assembly (e.g., holder assembly 274) and may be spaced the appropriate distance (e.g., 10 μm) from the corresponding surface of the movement restriction assemblies (e.g., movement restriction assemblies 266, 268). Holder assembly 274 may be configured to contain/mount IR filter 276 and/or lens assembly 278.

### General:

In general, the various operations of method described herein may be accomplished using or may pertain to components or features of the various systems and/or apparatus with their respective components and subcomponents, described herein.

The presence of broadening words and phrases such as “one or more,” “at least,” “but not limited to” or other like phrases in some instances shall not be read to mean that the narrower case is intended or required in instances where such broadening phrases may be absent.

Additionally, the various embodiments set forth herein are described in terms of example block diagrams, flow charts and other illustrations. As will become apparent to one of ordinary skill in the art after reading this document, the illustrated embodiments and their various alternatives can be implemented without confinement to the illustrated examples. For example, block diagrams and their accompanying description should not be construed as mandating a particular architecture or configuration.

While various embodiments of the present disclosure have been described above, it should be understood that they have been presented by way of example only, and not of limitation. Likewise, the various diagrams may depict an example architectural or other configuration for the disclosure, which is done to aid in understanding the features and functionality that can be included in the disclosure. The disclosure is not restricted to the illustrated example architectures or configurations, but the desired features can be implemented using a variety of alternative architectures and configurations. Indeed, it will be apparent to one of skill in the art how alternative functional, logical or physical partitioning and configurations can be implemented to implement the desired features of the present disclosure. Additionally, with regard to flow diagrams, operational descriptions and method claims, the order in which the steps are presented herein shall not mandate that various embodiments be implemented to perform the recited functionality in the same order unless the context dictates otherwise.

Although the disclosure is described above in terms of various example embodiments and implementations, it should be understood that the various features, aspects and functionality described in one or more of the individual embodiments are not limited in their applicability to the particular embodiment with which they are described, but instead can be applied, alone or in various combinations, to one or more of the other embodiments of the disclosure, whether or not such embodiments are described and whether or not such features are presented as being a part of a described embodiment. Thus, the breadth and scope of the present disclosure should not be limited by any of the above-described example embodiments, and it will be understood by those skilled in the art that various changes and modifications to the previous descriptions may be made within the scope of the claims.

As will be appreciated by one skilled in the art, the present disclosure may be embodied as a method, a system, or a computer program product. Accordingly, the present disclosure may take the form of an entirely hardware embodiment, an entirely software embodiment (including firmware, resident software, micro-code, etc.) or an embodiment combining software and hardware aspects that may all generally be referred to herein as a “circuit,” “module” or “system.” Furthermore, the present disclosure may take the form of a computer program product on a computer-usable storage medium having computer-usable program code embodied in the medium.

Any suitable computer usable or computer readable medium may be utilized. The computer-usable or computer-readable medium may be, for example but not limited to, an electronic, magnetic, optical, electromagnetic, infrared, or semiconductor system, apparatus, device, or propagation medium. More specific examples (a non-exhaustive list) of the computer-readable medium may include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a transmission media such as those supporting the Internet or an intranet, or a magnetic storage device. The computer-usable or computer-readable medium may also be paper or another suitable medium upon which the program is printed, as the program can be electronically captured, via, for instance, optical scanning of the paper or other medium, then compiled, interpreted, or otherwise processed in a suitable manner, if necessary, and then stored in a computer memory. In the context of this document, a computer-usable or computer-readable medium may be any medium that can contain, store, communicate, propagate, or transport the program for use by or in connection with the instruction execution system, apparatus, or device. The computer-usable medium may include a propagated data signal with the computer-usable program code embodied therewith, either in baseband or as part of a carrier wave. The computer usable program code may be transmitted using any appropriate medium, including but not limited to the Internet, wireline, optical fiber cable, RF, etc.

Computer program code for carrying out operations of the present disclosure may be written in an object oriented programming language such as Java, Smalltalk, C++ or the like. However, the computer program code for carrying out operations of the present disclosure may also be written in conventional procedural programming languages, such as the “C” programming language or similar programming languages. The program code may execute entirely on the user's computer, partly on the user's computer, as a stand-alone software package, partly on the user's computer and partly on a remote computer or entirely on the remote computer or server. In the latter scenario, the remote computer may be connected to the user's computer through a local area network/a wide area network/the Internet (e.g., network 18).

The present disclosure is described with reference to flowchart illustrations and/or block diagrams of methods, apparatus (systems) and computer program products according to embodiments of the disclosure. It will be understood that each block of the flowchart illustrations and/or block diagrams, and combinations of blocks in the flowchart illustrations and/or block diagrams, may be implemented by computer program instructions. These computer program instructions may be provided to a processor of a general purpose computer/special purpose computer/other programmable data processing apparatus, such that the instructions, which execute via the processor of the computer or other programmable data processing apparatus, create means for implementing the functions/acts specified in the flowchart and/or block diagram block or blocks.

These computer program instructions may also be stored in a computer-readable memory that may direct a computer or other programmable data processing apparatus to function in a particular manner, such that the instructions stored in the computer-readable memory produce an article of manufacture including instruction means which implement the function/act specified in the flowchart and/or block diagram block or blocks.

The computer program instructions may also be loaded onto a computer or other programmable data processing apparatus to cause a series of operational steps to be performed on the computer or other programmable apparatus to produce a computer implemented process such that the instructions which execute on the computer or other programmable apparatus provide steps for implementing the functions/acts specified in the flowchart and/or block diagram block or blocks.

The flowcharts and block diagrams in the figures may illustrate the architecture, functionality, and operation of possible implementations of systems, methods and computer program products according to various embodiments of the present disclosure. In this regard, each block in the flowchart or block diagrams may represent a module, segment, or portion of code, which comprises one or more executable instructions for implementing the specified logical function(s). It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustrations, and combinations of blocks in the block diagrams and/or flowchart illustrations, may be implemented by special purpose hardware-based systems that perform the specified functions or acts, or combinations of special purpose hardware and computer instructions.

The terminology used herein is for the purpose of describing particular embodiments only and is not intended to be limiting of the disclosure. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The corresponding structures, materials, acts, and equivalents of all means or step plus function elements in the claims below are intended to include any structure, material, or act for performing the function in combination with other claimed elements as specifically claimed. The description of the present disclosure has been presented for purposes of illustration and description, but is not intended to be exhaustive or limited to the disclosure in the form disclosed. Many modifications and variations will be apparent to those of ordinary skill in the art without departing from the scope and spirit of the disclosure. The embodiment was chosen and described in order to best explain the principles of the disclosure and the practical application, and to enable others of ordinary skill in the art to understand the disclosure for various embodiments with various modifications as are suited to the particular use contemplated.

A number of implementations have been described. Having thus described the disclosure of the present application in detail and by reference to embodiments thereof, it will be apparent that modifications and variations are possible without departing from the scope of the disclosure defined in the appended claims.

What is claimed is:

1. A spacer assembly comprising:
an essentially-planer structural portion configured to position an image sensor on a MEMS actuator;
an outer sub-portion configured to be mounted to the MEMS actuator; and
an inner sub-portion configured to mount the image sensor.

2. The spacer assembly of claim 1 wherein the outer sub-portion is configured to be mounted to the MEMS actuator with an epoxy.

3. The spacer assembly of claim 1 wherein the inner sub-portion is configured to mount the image sensor with an epoxy.

4. The spacer assembly of claim 1 wherein the essentially-planer structural portion includes one or more relief assemblies configured to enable electrically-connecting the image sensor and the MEMS actuator.

5. The spacer assembly of claim 1 wherein the essentially-planer structural portion includes one or more movement restriction assemblies configured to prevent undesired movement of the image sensor.

6. The spacer assembly of claim 5 wherein the undesired movement of the image sensor includes drop-induced movement of the image sensor.

7. The spacer assembly of claim 5 wherein the one or more movement restriction assemblies are configured to limit movement in the X axis & Y axis.

8. The spacer assembly of claim 5 wherein the one or more movement restriction assemblies are configured to essentially prevent movement in the Z axis.

9. The spacer assembly of claim 5 wherein the one or more movement restriction assemblies are configured to interface with one or more stop assemblies.

10. The spacer assembly of claim 9 wherein the one or more stop assemblies are a portion of a holder assembly.

11. The spacer assembly of claim 1 wherein the spacer assembly is constructed of metal.

12. A spacer assembly comprising:
an essentially-planer structural portion configured to position an image sensor on a MEMS actuator;
an outer sub-portion configured to be mounted to the MEMS actuator with an epoxy; and
an inner sub-portion configured to mount the image sensor with an epoxy.

13. The spacer assembly of claim 12 wherein the essentially-planer structural portion includes one or more relief assemblies configured to enable electrically-connecting the image sensor and the MEMS actuator.

14. The spacer assembly of claim 12 wherein the essentially-planer structural portion includes one or more movement restriction assemblies configured to prevent undesired movement of the image sensor.

15. The spacer assembly of claim 14 wherein the undesired movement of the image sensor includes drop-induced movement of the image sensor.

16. The spacer assembly of claim 14 wherein the one or more movement restriction assemblies are configured to limit movement in the X axis & Y axis.

17. The spacer assembly of claim 14 wherein the one or more movement restriction assemblies are configured to essentially prevent movement in the Z axis.

18. The spacer assembly of claim 14 wherein the one or more movement restriction assemblies are configured to interface with one or more stop assemblies.

19. The spacer assembly of claim 18 wherein the one or more stop assemblies are a portion of a holder assembly.

20. A spacer assembly comprising:
an essentially-planer structural portion configured to position an image sensor on a MEMS actuator;
an outer sub-portion configured to be mounted to the MEMS actuator; and
an inner sub-portion configured to mount the image sensor;
wherein the essentially-planer structural portion includes one or more movement restriction assemblies configured to prevent undesired movement of the image sensor.

21. The spacer assembly of claim 20 wherein the undesired movement of the image sensor includes drop-induced movement of the image sensor.

22. The spacer assembly of claim 20 wherein the one or more movement restriction assemblies are configured to limit movement in the X axis & Y axis.

23. The spacer assembly of claim 20 wherein the one or more movement restriction assemblies are configured to essentially prevent movement in the Z axis.

24. The spacer assembly of claim 20 wherein the one or more movement restriction assemblies are configured to interface with one or more stop assemblies.

25. The spacer assembly of claim 24 wherein the one or more stop assemblies are a portion of a holder assembly.
